(19) United States
(12) Patent Application Publication
(10) Pub. No.: US 2012/0106760 A1
(43) Pub. Date: May 3, 2012

(54) AUDIO AMP WITH SPURIOUS WAVE NOISE REDUCTION CIRCUIT

(75) Inventor: IL Hwan Kim, Gunpo-si (KR)

(73) Assignee: M DESIGNS INC, Gunpo-si (KR)

(21) Appl. No.: 13/129,536

(22) PCT Filed: Mar. 22, 2010
(86) PCT No.: PCT/KR2010/001741

§ 371 Date: May 16, 2011

(30) Foreign Application Priority Data
Jun. 17, 2009 (KR) 10-2009-0053810

(51) Int. Cl. H03F 99/00

(52) U.S. Cl. 381/120

(57) ABSTRACT

An audio amplifier with a spurious wave noise reduction circuit according to the present invention comprises: an input unit receiving the audio signal for each channel; a modulation unit converting the audio signal into a pulse width modulation (PWM) signal; an amplification unit amplifying the PWM signal; an output unit extracting the audio signal from the amplified PWM signal to output; a power supply applying power to the input unit, the modulation unit, the amplification unit, and the output unit; and a pulse generation unit generating a first reference signal that is a pulse signal applied to the modulation unit and a second reference signal that is a pulse signal applied to the power supply. In the amplifier of the present invention, the first reference signal is applied to the modulation unit to synchronize the PWM signal with respect to the audio signal for each channel, and the second reference signal is applied to the power supply to synchronize the pulse signal generated in the power supply with the PWM signal to reduce spurious wave noise occurring in the audio amplifier.

### TECHNICAL FIELD

The present invention relates to an audio amplifier device using a pulse width modulation (PWM) circuit, and more particularly, to an audio amplifier which applies a reference signal capable of synchronizing the pulse width modulation frequency to an amplification unit and power supply in the audio amplifier, thereby significantly reducing a spurious wave noise due to a frequency interference occurred in the audio amplifier which uses the pulse width modulation circuit.

### BACKGROUND ART

Conventionally, the audio amplifier for amplifying an audio signal is classified into a Class A, a Class B, a Class AB, and a Class D output stage amplifier in accordance with operations of an output stage.

The Class A output stage amplifier has disadvantages in that it causes large heat generation amount and low efficiency because a bias voltage is applied to the output transistors when operating in a no-signal state, i.e., mute state to cause the bias current to flow.

The Class B output stage amplifier has a structure of the bias current being zero when operating in the no-signal state. However, since the upper and lower transistors of a driving circuit turn off when the output signal passes through near a reference voltage, crossover transformation occurs greatly.

The Class AB output stage amplifier has a structure of small amount of vias current being flowed in the no-signal state considering a low transformation property of the Class A and a high efficiency property of the Class B. However, since the amount of heat generation is still large, large heatsink is still necessary and the crossover transformation is exhibited.

The Class D output stage amplifier is characterized by having high efficiency of greater than 90% since turn-on resistance of the components outputted by the amplifier which is configured with the output stage operated using the pulse width modulation driving circuit is too small.

Therefore, the class D output stage amplifier of high efficiency has been widely developed.

FIG. 1 shows a block diagram of audio amplifier having the class D output stage using the pulse width modulation circuit according to the prior art.

The conventional audio amplifier converts the audio signal into a PWM signal which is one form of the digital signal and amplifier it to be reproduced as an original analogue signal through a low pass filtering.

Generally, in a case of the class D amplifier, after the audio signal is inputted into the modulation unit 200, the PWM signal modulated in the modulation unit 200 is amplified in the amplification unit 300 and then outputted as the analogue signal via the low-pass filter 400.

Herein, it is preferable that the PWM signal is amplified because the PWM signal itself modulated in the modulation unit 200 has too low output power to drive the speaker directly.

The amplification unit 300 is generally configured with a gate driver and a switching element, in which a MOSFET (Metal Oxide Semiconductor Field Effect Transistor) suitable for switching the large current at a high speed is mainly used as the switching element.

Such amplified PWM signal has the spurious wave noise occurred when it is suddenly applied to the speaker.

Since the power supply 600 and the amplification unit 300 use circuits accompanied with the pulse width modulation technology, a difference between the frequencies of the pulse signals generated in the power supply 600 and the amplification unit 300 may prevent the frequencies from being synchronized, and the spurious wave component occurred due to overlapping frequencies is outputted to the speaker via the power supply line or the amplification unit 300, which results in a beat noise, a whistle noise, and even radio wave that influences on receiving AM broadcasting.

### DISCLOSURE

### Technical Problem

An object of the present invention is to provide an audio amplifier with a spurious wave noise reduction circuit comprising a pulse generation unit for generating a reference signal, which applies the reference signal capable of synchronizing the pulse width modulation frequencies to an amplification unit and a power supply of the audio amplifier, thereby significantly reducing the spurious wave noise due to a frequency interference occurring in the audio amplifier which uses a pulse width modulation (PWM) circuit.

### Technical Solution

To achieve the object of the present invention, the present invention provides an audio amplifier with a spurious wave noise reduction circuit for amplifying an audio signal in a pulse width modulation type, including an input unit receiving the audio signal for each channel; a modulation unit converting the audio signal into a pulse width modulation (PWM) signal; an amplification unit amplifying the PWM signal; an output unit extracting the audio signal from the amplified PWM signal to output; a power supply applying power to the input unit, the modulation unit, the amplification unit, and the output unit; and a pulse generation unit generating a first reference signal that is a pulse signal applied to the modulation unit and a second reference signal that is a pulse signal applied to the power supply, wherein the first reference signal is applied to the modulation unit to synchronize the PWM signal with respect to the audio signal for each channel, and the second reference signal is applied to the power supply to synchronize the pulse signal generated in the power supply with the PWM signal to reduce spurious wave noise occurring in the audio amplifier.

Preferably, the pulse generation unit generates the first reference signal and the second reference signal as the pulse signal of synchronizing frequency having a multiplication frequency relation.

More preferably, the synchronizing frequency is in a frequency range of at least AM carrier frequency band.

Further, the generation unit is provided as an oscillator element including a buffer and flip-flops.

Further, the power supply includes a DCDC converter for changing a voltage level of power source applied by the switching circuit and a transformer circuit for converting the power source into a voltage necessary for each component of the audio amplifier.

Herein, the second reference signal is applied to an input stage of the DCDC converter.

Further, the input unit further includes a gain adjust for amplifying the audio signal in accordance with a gain ratio to be adjusted.

Further, the amplification unit includes gate drivers and MOSFET (Metal Oxide Semiconductor Field Effect Transistor) circuits.

Herein, the MOSFET circuit is configured with a class D driving circuit of half-bridge type.

Herein, the gate driver includes a level shifter for shifting a reference voltage of the pulse width modulation signal to drive the MOSFETs, a dead-time generation circuit for preventing two power MOSFETs from simultaneously being turned on, and a bootstrap circuit which functions as a floating power source.

Further, the output unit may include a low pass filter circuit.

### ADVANTAGEOUS EFFECTS

Subsequently, the audio amplifier according to the present invention may apply the reference signal capable of synchronizing the pulse width modulation frequencies with each other to an amplification unit and a power supply in the audio amplifier, thereby significantly reducing spurious wave noise due to frequency interference occurring in the audio amplifier which uses the pulse width modulation (PWM) circuit.

### DESCRIPTION OF DRAWINGS

The above and other objects, features and advantages of the present invention will become apparent from the following description of preferred embodiments given in conjunction with the accompanying drawings, in which:

FIG. 1 is a block diagram of an audio amplifier using a pulse width modulation (PWM) circuit according to a prior art.

FIG. 2 is a block diagram showing a structure of the audio amplifier with a spurious wave noise reduction circuit according to the present invention.

FIG. 3 is a schematic equivalent circuit diagram of an audio amplifier with a spurious wave noise reduction circuit according to the present invention.

FIG. 4 is a block diagram showing a structure of a power supply in an audio amplifier with a spurious wave noise reduction circuit according to the present invention.

FIG. 5 is a drawing showing a pulse generation unit in an audio amplifier with a spurious wave noise reduction circuit according to the present invention.

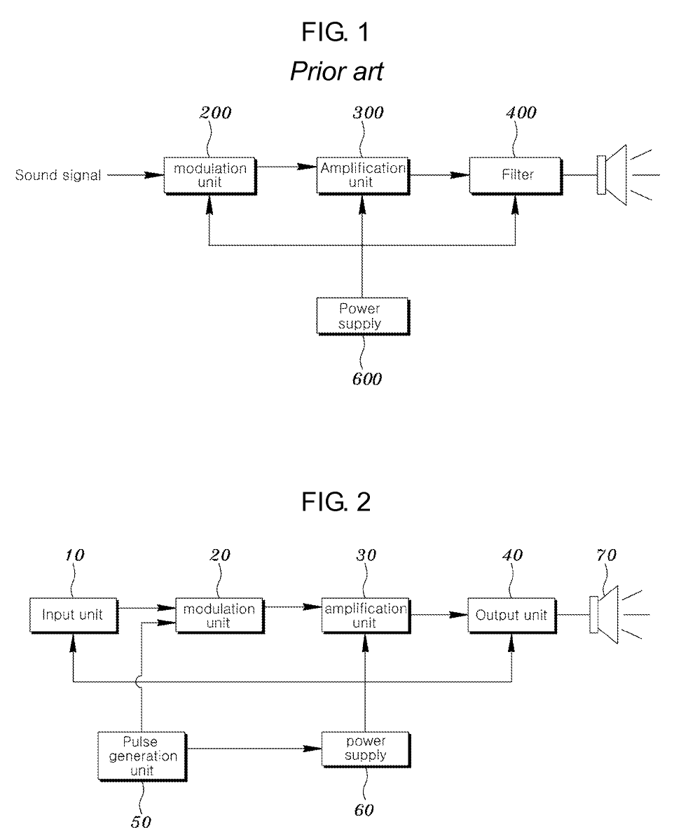

[Detailed Description of Main Elements]

| | |
|---|---|
| 10: input unit | 20: modulation unit |
| 30: amplification unit | 40: output unit |
| 50: pulse generation unit | 60: power supply |

### BEST MODE

Hereinafter, the embodiments of the present invention will be described in detail with reference to accompanying drawings.

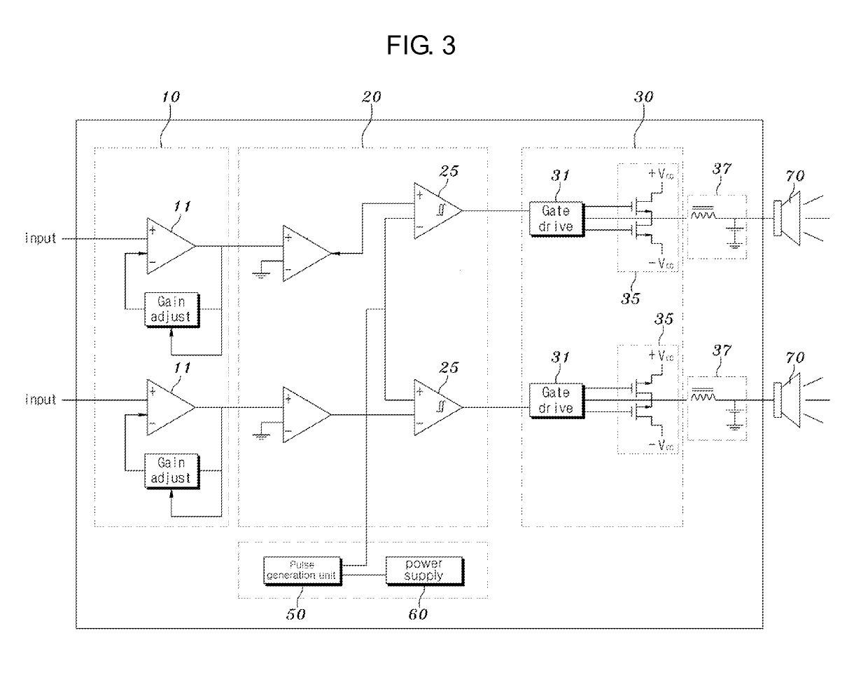

FIG. 2 is a block diagram showing a structure of the audio amplifier with a spurious wave noise reduction circuit according to the present invention, and FIG. 3 is a schematic equivalent circuit diagram of an audio amplifier with a spurious wave noise reduction circuit according to the present invention.

Referring to FIG. 2 and FIG. 3, the digital amplifier according to the present invention includes an input unit 10 receiving an audio signal, a modulation unit 20 converting the audio signal into a pulse width modulation (PWM) signal, amplification unit 30 amplifying the PWM signal, an output unit 40 extracting an audio signal from the amplified PWM signal to output, a power supply 60 generating a power signal to apply power source to the input unit 10, the modulation unit 20, the amplification unit 30, and the output unit 40, and a pulse generation unit 50 generating a first reference signal Q4 that is a pulse signal applied to the amplification unit and a second reference signal Q7 that is a pulse signal applied to the power supply 60.

The input unit 10 receives various audio signal inputted via various sound equipments.

The audio signal includes a digital audio source such as CD player or an audio signal generating in a radio frequency band such as AM and FM.

The audio signal inputted to the input unit 10 is amplified in accordance with a gain ratio adjusted via a gain adjust 11 which performs to control an audio volume and then transmitted to the modulation unit 20.

The modulation unit 20 is responsible for converting the audio signal into the pulse width modulation signal to generate the PWM output signal by comparing the audio signal with a triangle wave generated in the pulse generation unit 50 at the comparator 25.

The amplification unit 30 receives the PWM signal generated in the modulation unit 20 and then amplifies it. It is generally configured with gate drivers 31 and switching elements 35, and as the switching element, a MOSFET (Metal Oxide Semiconductor Field Effect Transistor) suitable for switching the high current at a high speed is mainly used.

The class D driving circuit of half-bridge type using the MOSFET is applied to the present invention.

The class D driving circuit of half-bridge type has two MOSFETs overlapped with each other up and down, and the output unit 40 is connected at the point in which an upper MOSFET and a lower MOSFET are connected.

Herein, the gate driver 31 includes a level shifter which shifts the reference voltage of the PWM signal to drive the MOSFETs, a dead-time generation circuit which prevents the two

MOSFETs from being simultaneously turned on, and a bootstrap circuit which functions as a floating power source.

The output unit 40 is responsible for extracting the audio signal from the PWM signal amplified in the amplification unit 30 to output it to the speaker 70. In the present invention, the output unit 40 is configured with a low pass filter circuit to extract the audio signal simply.

Herein, the audio signal outputted in the output unit 40 has the spurious wave noise due to the interference component between the frequencies since the frequencies of the pulse signal used for the PWM are different from each other for each channel and thus overlapped to each other.

Subsequently, the present invention further includes the pulse generation unit 50 generating the first reference signal Q4 to synchronize the PWM signal for each channel which is generated in the modulation unit 20, thereby to eliminate the spurious wave component and minimize the noise occurrence.

The power supply 60 is to apply a power source (Vref, Agnd, and Vcc) to circuit elements configured in the input unit 10, the modulation unit 20, the amplification unit 30, and the output unit 40. The power supply 60 according to the present invention may be small-sized by using a switching circuit of high energy conversion efficiency.

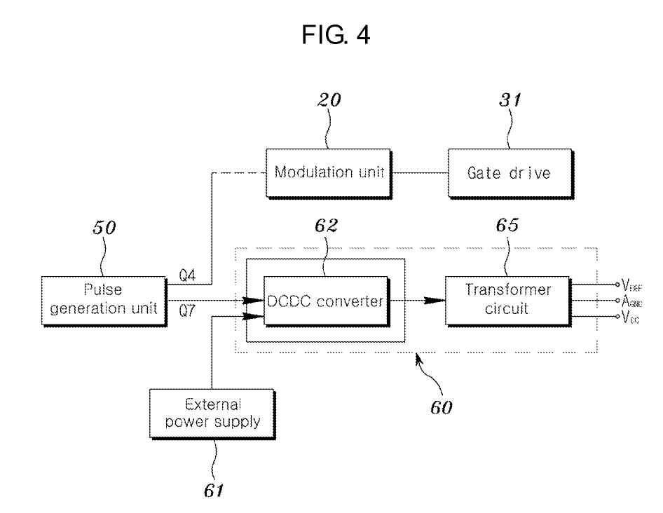

Subsequently, the power supply 60 includes a DCDC converter 62 which changes the voltage level of the power source applied by the switching circuit from an external power supply 61 and a transformer circuit 65 which may change the power source into the voltage necessary for each component of the audio amplifier, as shown in FIG. 4 illustrating a structure of the power supply 60 of the audio amplifier according to the present invention.

Herein, the pulse signal generated by the DCDC converter 62 in the power supply 60 is contained in the power source and overlapped with the PWM signal to generate the spurious wave noise due to the interference component between the frequencies.

Such spurious wave noise is generated in a form of the beat noise, the whistle noise, so that it may distort sounds outputted from the speaker 70 and even influence on receiving the AM broadcasting.

Subsequently, the pulse generation unit 50 is configured to generate the second reference signal Q7 for synchronizing the pulse signal generated by the power supply 60, in order to reduce the spurious wave noise mentioned above, according to the present invention.

Herein, the second reference signal Q7 is applied to the power supply to synchronize the pulse signal generated in the power supply with the PWM signal which is synchronized by the first reference signal Q4.

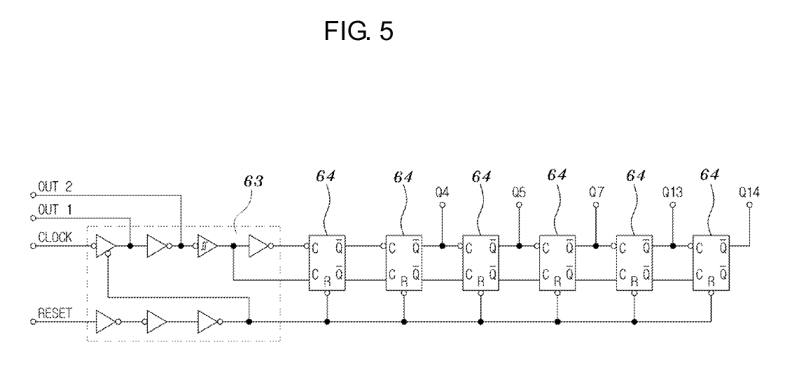

FIG. 5 is a drawing showing the pulse generation unit in the audio amplifier according to the present invention.

The pulse generation unit 50 generates the first reference signal Q4 and the second reference signal Q7 to synchronize the pulse signal generated in the modulation unit 20 and the power supply 60 to reduce the spurious wave noise occurring in the audio amplifier.

Further, the first reference signal Q4 is activated in response to the PWM signal and the second reference signal Q7 is activated in response to the pulse signal generated in the DCDC converter 62 in the power supply 60.

Herein, the pulse generation unit 50 may be provided as an oscillator element including a buffer 63 and flip-flops 64, as shown in FIG. 5.

The flip-flops 64 generates the first reference signal Q4 and the second reference signal Q7 which are pulse signals obtained by shifting the clock signals of the pulse generation unit 50 into a synchronizing frequency to reduce the spurious wave noise. The buffer 63 prevents the first reference signal Q4 and the second signal Q7 generated by the flip-flops 64 from being refluxed to the clock signal.

Herein, the first reference signal Q4 and the second reference signal Q7 are configured to be oscillated in a multiplication relation with a frequency difference between the PWM signal and the pulse signal generated in the power supply 60 to cause them to be easily synchronized.

For the purpose of it, the pulse generation unit 50 has a plurality of flip-flops 64, to generate the synchronizing frequency signal from the pulse signals having the multiplication frequency relations Q4, Q5, . . . , Q13, Q14 occurred via each flip-flop 64, as the first reference signal Q4 and the second reference signal Q7.

More specifically, the pulse generation unit 50 generates the first reference signal Q4 and the second reference signal Q7 by comparing the PWM signal with the pulse signal generated in the power supply 60 to oscillate the frequency component which is determined to align with the synchronizing frequency from the frequency components multiplying the clock signal 8 times, 16 times, 24 times.

The synchronizing frequency may preferably be synchronized in the frequency band to minimize the interference which may influence the digital audio source such as CD player or the radio frequency band such as AM and FM.

Particularly, since a harmonic wave frequency of the PWM included in the spurious wave noise is overlapped with a carrier frequency of the AM broadcasting signal, the interference is frequently occurred in the AM broadcasting signal. For the purpose of preventing it, the synchronizing frequency is preferably controlled to have the frequency of at least the AM carrier frequency band.

For example, if the audio signal having sampling frequency of 22 kHz for each channel is modulated into 16 bit PMW signal, the pulse width modulation signal modulated in the modulation unit 20 has the frequency of 16×22 kHz, i.e., 352 kHz.

The pulse width modulation signal having the frequency of 352 kHz has a second harmonic wave having the frequency of 704 kHz, a third harmonic wave having the frequency of 1056 kHz and a forth harmonic wave having the frequency of 1408 kHz.

Such frequencies having harmonic components in the PWM signal are overlapped with each other to generate the spurious wave noise and thus cause the interference in the carrier frequency of the AM broadcasting signal.

Therefore, the pulse generation unit 50 generates the first reference signal Q4 and the second reference signal Q7 which may control the sampling of the PWM signal and the pulse signal generated in the power supply, so that the frequencies of the PWM signal and the pulse signal generated in the power supply 60 may be changed to have the synchronizing frequency of the frequency band mentioned above. As a result, it is possible to reduce the interference influencing the carrier frequency of the AM broadcasting signal and the spurious wave noise generated in the speaker 70, through the frequency filtering of the output unit 40.

Herein, the first reference signal Q4 and the second reference signal Q7 preferably allow the frequencies of the PWM signal and the pulse signal generated in the power supply to be oscillated and synchronized in a frequency of 396 kHz band of multiplication relation with 22 Khz of the sampling frequency at the amplification unit, thereby synchronizing them simply while minimizing the interference influencing the carrier frequency of the AM broadcasting signal.

The contents disclosed in the specification and the terms used in the claims must not be limited and interpreted as a dictionary meaning, but must be interpreted as meanings and concepts conforming to the technical idea of the present invention, in view of principles which may properly define the concepts of the terms to explain the present invention in a best mode.

While the present invention has been described with respect to the specific embodiments, it will be apparent to those skilled in the art that various changes and modifications may be made without departing from the spirit and scope of the invention as defined in the following claims.

### INDUSTRIAL APPLICABILITY

The present invention may be applied to the audio amplifier to significantly reduce the spurious wave noise occurred due to the frequency interference.

1. An audio amplifier with a spurious wave noise reduction circuit for amplifying an audio signal in a pulse width modulation type, comprising:
an input unit receiving the audio signal for each channel;
a modulation unit converting the audio signal into a pulse width modulation (PWM) signal;
an amplification unit amplifying the PWM signal;
an output unit extracting the audio signal from the amplified PWM signal to output;
a power supply applying power to the input unit, the modulation unit, the amplification unit, and the output unit; and
a pulse generation unit generating a first reference signal that is a pulse signal applied to the modulation unit and a second reference signal that is a pulse signal applied to the power supply,
wherein the first reference signal is applied to the modulation unit to synchronize the PWM signal with respect to the audio signal for each channel, and the second reference signal is applied to the power supply to synchronize the pulse signal generated in the power supply with the PWM signal to reduce spurious wave noise occurring in the audio amplifier.

2. The audio amplifier with the spurious wave noise reduction circuit of claim 1, wherein the pulse generation unit generates the first reference signal and the second reference signal as the pulse signal of synchronizing frequency having a multiplication frequency relation.

3. The audio amplifier with the spurious wave noise reduction circuit of claim 2, wherein the synchronizing frequency is in a frequency range of at least AM carrier frequency band.

4. The audio amplifier with the spurious wave noise reduction circuit of claim 3, wherein the pulse generation unit is provided as an oscillator element including a buffer and flip-flops.

5. The audio amplifier with the spurious wave noise reduction circuit of claim 1, wherein the power supply comprises a DCDC converter for changing a voltage level of power source applied by the switching circuit and a transformer circuit for converting the power source into a voltage necessary for each component of the audio amplifier.

6. The audio amplifier with the spurious wave noise reduction circuit of claim 5, wherein the second reference signal is applied to an input stage of the DCDC converter.

7. The audio amplifier with the spurious wave noise reduction circuit of claim 1, wherein the input unit further comprises a gain adjust for amplifying the audio signal in accordance with a gain ratio to be adjusted.

8. The audio amplifier with the spurious wave noise reduction circuit of claim 1, wherein the amplification unit comprises gate drivers and MOSFET (Metal Oxide Semiconductor Field Effect Transistor) circuits.

9. The audio amplifier with the spurious wave noise reduction circuit of claim 8, wherein the MOSFET circuit is configured with a class D driving circuit of half-bridge type.

10. The audio amplifier with the spurious wave noise reduction circuit of claim 9, wherein the gate driver comprises a level shifter for shifting a reference voltage of the pulse width modulation signal to drive the MOSFETs, a dead-time generation circuit for preventing two power MOSFETs from simultaneously being turned on, and a bootstrap circuit which functions as a floating power source.

11. The audio amplifier with the spurious wave noise reduction circuit of claim 1, wherein the output unit comprises a low pass filter circuit.
